(19) United States
(12) Patent Application Publication
(10) Pub. No.: US 2026/0312596 A1
(43) Pub. Date: Oct. 8, 2026

(54) PHASE-LOCKED LOOP AND METHOD OF OPERATING THE SAME

(71) Applicant: SK hynix Inc., Icheon-si (KR)

(72) Inventor: Jae Min SHIM, Icheon-si (KR)

(21) Appl. No.: 19/306,416

(22) Filed: Aug. 21, 2025

(30) Foreign Application Priority Data
Apr. 2, 2025 (KR) 10-2025-0042594

(51) Int. Cl. H03L 7/199; H03L 7/099

(52) U.S. Cl. CPC H03L 7/199; H03L 7/0992

(57) ABSTRACT

A phase-locked loop includes: a voltage generator generating a control voltage that increases or decreases depending on whether UP and DOWN signals are enabled, an oscillator generating a first clock signal toggling at a frequency corresponding to the control voltage, a reset signal generator synchronizing a first reset signal with the first clock signal to generate a second reset signal, a phase detector detecting a phase difference between a second clock signal and a third clock signal obtained by feeding back the first clock signal, determining whether to enable the UP and DOWN signals, and maintaining the UP signal disabled and the DOWN signal enabled during a reset preparation period from when the first reset signal is enabled to when the second reset signal is enabled, and a lock determiner generating a lock signal indicating whether locking is completed, in response to the UP and DOWN signals.

### CROSS-REFERENCE TO RELATED APPLICATION

This application claims priority under 35 U.S.C. §119(a) to Korean Patent Application No. 10-2025-0042594, filed in the Korean Intellectual Property Office on Apr. 02, 2025, the entire contents of which are incorporated herein by reference.

### BACKGROUND

### 1. Field

Various embodiments relate to semiconductor technology, and specifically, to a phase-locked loop and a method of operating the phase-locked loop.

### 2. Discussion of the Related Art

A phase-locked loop (PLL) is a circuit for performing a locking operation of comparing a phase of an external clock input from an exterior with a phase of an internal clock generated therein, changing a frequency of the internal clock according to the comparison result, and synchronizing the phase of the external clock with the phase of the internal clock. A PLL is one of the basic circuits generally provided in an integrated circuit such as a semiconductor device.

When a phase difference between an external clock and an internal clock is equal to or less than a phase difference defined in advance by a plurality of delay cells, a general phase-locked loop judges that the phases of the external clock and the internal clock have been synchronized with each other and thus determines locking completion.

To turn off or initialize a phase-locked loop, an external reset signal that is not synchronized with a frequency of an internal clock signal may be used. Because a time point at which the phase-locked loop is turned off or initialized is not predetermined, conventional methods have been used. For example, an external reset signal, which is not synchronized with the internal clock signal generated by the phase-locked loop, is input to the phase-locked loop without consideration of the frequency of the internal clock signal, and then the phase-locked loop is turned off or initialized by synchronizing the external reset signal with the internal clock signal.

When the frequency of the internal clock signal generated by the phase-locked loop is relatively low, the phase-locked loop can be turned off or initialized without any problems even when an external reset signal is used.

However, when the frequency of the internal clock signal generated by the phase-locked loop is relatively high, the phase-locked loop may not be properly turned off or initialized, depending on a time point at which the external reset signal is input, thereby causing problems such as malfunction of the phase-locked loop.

### SUMMARY

Various embodiments are directed to providing a phase-locked loop, which can be stably turned off or initialized regardless of a time point at which an external reset signal is input or the frequency of an internal clock signal of the phase-locked loop, and a method of operating the phase-locked loop.

The problems to be solved by the present disclosure are not limited to the above-mentioned problems, and the other problems not mentioned here will be clearly understood by those skilled in the art to be addressed by the following description.

An aspect of an embodiment in the invention, a phase-locked loop comprising: a voltage generator configured to generate a control voltage that increases or decreases in voltage level depending on whether each of an UP signal and a DOWN signal is enabled; an oscillator configured to generate a first clock signal that toggles at a frequency corresponding to a level of the control voltage; a reset signal generator configured to synchronize a first reset signal input from an external device with the first clock signal, and to generate a second reset signal; a phase detector configured to detect a phase difference between a second clock signal input from an external device and a third clock signal obtained by feeding back the first clock signal, to determine whether to enable each of the UP signal and the DOWN signal, and to maintain the UP signal in a disabled state and the DOWN signal in an enabled state during a reset preparation period from a time point at which the first reset signal is enabled to a time point at which the second reset signal is enabled; and a lock determiner configured to generate a lock signal indicating whether locking is completed, in response to the UP signal and the DOWN signal.

An aspect of an embodiment in the invention, a method of operating a phase-locked loop, the method may include: increasing a level of a control voltage when an UP signal is in an enabled state, and decreasing the level of the control voltage when a DOWN signal is in an enabled state; generating a first clock signal toggling at a frequency corresponding to the level of the control voltage; generating a second reset signal by synchronizing a first reset signal input from an external device with the first clock signal; detecting, when both the first reset signal and the second reset signal are in a disabled state, a phase difference between a second clock signal input from an external device and a third clock signal obtained by feeding back the first clock signal, and determining whether to enable each of the UP signal and the DOWN signal; maintaining the UP signal in a disabled state and the DOWN signal in an enabled state during a reset preparation period corresponding to a state in which the first reset signal is in a disabled state and the second reset signal is in an enabled state; and maintaining both the UP signal and the DOWN signal in a disabled state when the both the first reset signal and the second reset signal are in a disabled state.

### BRIEF DESCRIPTION OF THE DRAWINGS

FIG. 1 is a diagram illustrating an example of a phase-locked loop according to an embodiment of the disclosure.

FIGS. 2A-2C are diagrams illustrating examples of a detailed operation of a phase detector among components of a phase-locked loop illustrated in FIG. 1 according to embodiments of the disclosure.

FIG. 3 is a diagram illustrating an example of a circuit of a voltage generator among the components of a phase-locked loop illustrated in FIG. 1 according to an embodiment of the disclosure.

FIGS. 4A and 4B are diagrams illustrating examples of detailed operations of circuits of a reset signal generator and a clock output component among the components of a phase-locked loop illustrated in FIG. 1 according to an embodiment of the disclosure.

FIGS. 5A-5D are diagrams illustrating examples of detailed operations of a circuit of a stabilizer included in a lock determiner among components of a phase-locked loop illustrated in FIG. 1 according to an embodiment of the disclosure.

FIG. 6 is a timing diagram during an operation of a phase-locked loop according to an embodiment of the disclosure.

FIGS. 7A and 7B are timing diagrams illustrating an operation of a stabilizer included in a lock determiner among components of the phase-locked loop illustrated in FIG. 1 according to an embodiment of the disclosure.

### DETAILED DESCRIPTION

Various embodiments of the present disclosure are described below with reference to the accompanying drawings. Elements and features of the disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms "comprise," "comprising," "include," and "including" are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, various units, circuits, or other components may be described or claimed as "configured to" perform a task or tasks. In such contexts, "configured to" is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated). Examples of block/unit/circuit/component used with the "configured to" language includes hardware-for example, circuits, memory storing program instructions executable to implement the operation, etc. Additionally, "configured to" can include a generic structure (e.g., generic circuitry) that is manipulated by software and/or firmware (e.g., an FPGA or a general-purpose processor executing software) to operate in a manner that is capable of performing the task(s) at issue. "Configured to" may also include adapting a manufacturing process (e.g., a semiconductor fabrication facility) to fabricate devices (e.g., integrated circuits) that implement or perform one or more tasks.

As used in the disclosure, the term 'circuitry' or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of 'circuitry' or ‘logic’ applies to all uses of this term in this application, including in any claims. As a further example, as used in this application, the term "circuitry" or “logic” also covers an implementation of merely a processor (or multiple processors) or a portion of a processor and its (or their) accompanying software and/or firmware. The term "circuitry" or “logic” also covers, for example, and if applicable to a particular claim element, an integrated circuit for a storage device.

As used herein, the terms "first," "second," "third," and so on are used as labels for nouns that the terms precede, and do not imply any type of ordering (e.g., spatial, temporal, logical, etc.). The terms "first" and "second" do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term "based on" is used to describe one or more factors that affect a determination. This term does not foreclose additional factors that may affect a determination. That is, a determination may be solely based on those factors or based, at least in part, on those factors. For example, the phrase "determine A based on B." While in this case, B is a factor that affects the determination of A, such a phrase does not foreclose the determination of A from also being based on C. In other instances, A may be determined based solely on B.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits. According to an embodiment, the data item may include a discrete object. According to another embodiment, the data item may include a unit of information within a transmission packet between two different components.

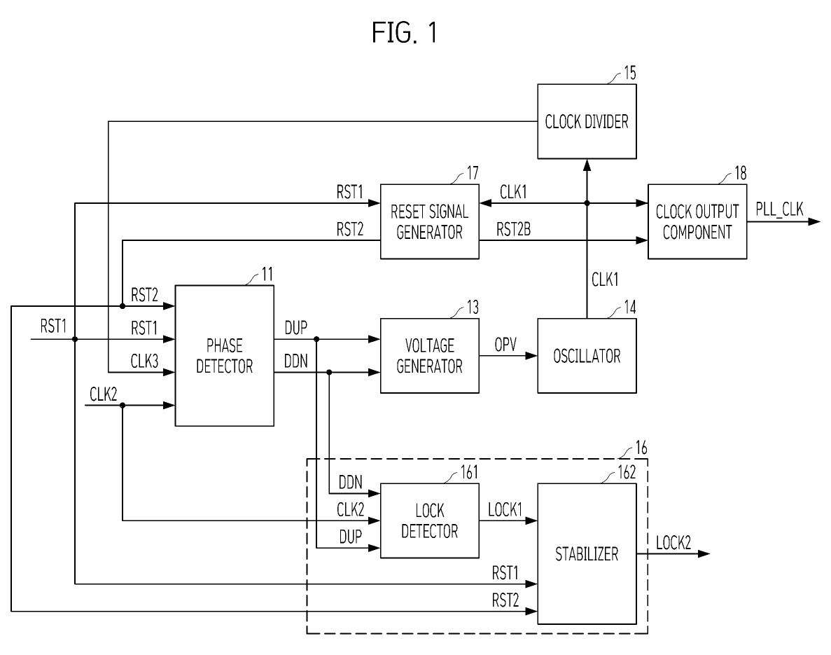

FIG. 1 is a diagram illustrating an example of a phase-locked loop according to an embodiment of the disclosure.

Referring to FIG. 1, a phase-locked loop according to an embodiment may include a phase detector 11, a voltage generator 13, an oscillator 14, a clock divider 15, a reset signal generator 17, a clock output component 18, and a lock determiner 16. The lock determiner 16 may include a lock detector 161 and a stabilizer 162.

For example, the voltage generator 13 generates a control voltage OPV that increases or decreases in voltage level depending on whether each of an UP signal DUP and a DOWN signal DDN is enabled. In other words, when the UP signal DUP is enabled, the voltage generator 13 may increase the level of the control voltage OPV that is generated. When the DOWN signal DDN is enabled, the voltage generator 13 may decrease the level of the control voltage OPV that is generated.

The oscillator 14 may generate a first clock signal CLK1 that toggles at a frequency corresponding to the level of the control voltage OPV. In other words, in response to an increase in the level of the control voltage OPV, the oscillator 14 may increase the frequency of the first clock signal CLK1 that is generated. In response to a decrease in the level of the control voltage OPV, the oscillator 14 may decrease the frequency of the first clock signal CLK1 that is generated.

The reset signal generator 17 may generate a second reset signal RST2 by synchronizing a first reset signal RST1, which is input from an external device, with the first clock signal CLK1. In other words, the reset signal generator 17 may generate the second reset signal RST2 by synchronizing an edge of the first reset signal RST1, which is input from the external device, with an edge of the first clock signal CLK1 generated by the oscillator 14. For example, the reset signal generator 17 generates the second reset signal RST2 by synchronizing a rising edge and a falling edge of the first reset signal RST1, that is, an edge where the first reset signal RST1 transitions from an enabled state to a disabled state and an edge where the first reset signal RST1 transitions from a disabled state to an enabled state, with a rising edge of the first clock signal CLK1. In another example, the reset signal generator 17 generates the second reset signal RST2 by synchronizing the rising edge and the falling edge of the first reset signal RST1, that is, an edge where the first reset signal RST1 transitions from an enabled state to a disabled state and an edge where the first reset signal RST1 transitions from a disabled state to an enabled state, with a falling edge of the first clock signal CLK1.

For example, during a preset number of toggles of the first clock signal CLK1, the reset signal generator 17 may output the first reset signal RST1 as the second reset signal RST2 by synchronizing the first reset signal RST1 with the first clock signal CLK1. For example, during three toggles of the first clock signal CLK1, the reset signal generator 17 outputs the first reset signal RST1 as the second reset signal RST2 by synchronizing the first reset signal RST1 with the first clock signal CLK1.

The phase detector 11 may detect a phase difference between a second clock signal CLK2 and a third clock signal CLK3. The second clock signal CLK2 may be a clock signal input from an external device. The third clock signal CLK3 may be a clock signal distributed at a preset ratio through the clock divider 15 from the first clock signal CLK1 generated by the oscillator 14.

In an embodiment, when a phase of the third clock signal CLK3 is later than that of the second clock signal CLK2, the phase detector 11 enables the UP signal DUP and disables the DOWN signal DDN. In this case, the voltage generator 13 may increase the level of the control voltage OPV beyond a current level. For example, when the level of the control voltage OPV that is currently generated is 300 mV, the voltage generator 13 may increase the level of the control voltage OPV to 320 mV in response to the UP signal DUP being in an enabled state and the DOWN signal DDN being in a disabled state.

In an embodiment, when a phase of the third clock signal CLK3 is earlier than that of the second clock signal CLK2, the phase detector 11 may disable the UP signal DUP and enable the DOWN signal DDN. In this case, the voltage generator 13 may decrease the level of the control voltage OPV below a current level. For example, when the level of the control voltage OPV that is currently generated is 300 mV, the voltage generator 13 may decrease the level of the control voltage OPV to 280 mV in response to the UP signal DUP being in a disabled state and the DOWN signal DDN being in an enabled state.

During a reset preparation period from an enable time point of the first reset signal RST1 to an enable time point of a second reset signal RST2, the phase detector 11 may maintain the UP signal DUP in a disabled state and the DOWN signal DDN in an enabled state.

The reset preparation period may correspond to a period required for the reset signal generator 17 to output the first reset signal RST1 as the second reset signal RST2 after synchronizing the first reset signal RST1 with the first clock signal CLK1. For example, if the reset signal generator 17 outputs the first reset signal RST1 as the second reset signal RST2 by synchronizing the first reset signal RST1 with the first clock signal CLK1 during three toggles of the first clock signal CLK1, then the reset preparation period may be a period during which the first clock signal CLK1 toggles three times.

Accordingly, the phase detector 11 may maintain the UP signal DUP in a disabled state and the DOWN signal DDN in an enabled state as the first clock signal CLK1 toggles a preset number of times (e.g., three times), such as from a time point at which the first reset signal RST1 transitions from a disabled state to an enabled state until a time point at which the second reset signal RST2 transitions from a disabled state to an enabled state.

If the phase detector 11 maintains the UP signal DUP in a disabled state and the DOWN signal DDN in an enabled state during the reset preparation period, then the level of the control voltage OPV generated by the voltage generator 13 may be continuously decreasing during the reset preparation period. Furthermore, the continuous decrease in the level of the control voltage OPV generated by the voltage generator 13 may indicate that the frequency of the first clock signal CLK1 generated by the oscillator 14 is continuously reducing.

The clock divider 15 may feed back the third clock signal CLK3, which is generated by dividing the first clock signal CLK1 at a preset ratio, to the phase detector 11. For example, the clock divider 15 feeds back the third clock signal CLK3, which is generated by dividing the phase of the first clock signal CLK1 by 256, to the phase detector 11.

The clock output component 18 may output the first clock signal CLK1 as an output clock signal PLL_CLK of the phase-locked loop in response to an inverted signal RST2B of the second reset signal RST2. In other words, the clock output component 18 may output the first clock signal CLK1 as the output clock signal PLL_CLK of the phase-locked loop, based on whether the second reset signal RST2, which is synchronized with the first clock signal CLK1, is in an enabled state.

The clock output component 18 may output the first clock signal CLK1 as the output clock signal PLL_CLK of the phase-locked loop during an enable period of a signal obtained by delaying the inverted signal RST2B of the second reset signal RST2 by a set time SDLY.

For example, the clock output component 18 may output the first clock signal CLK1, which is generated by the oscillator 14, as the output clock signal PLL_CLK of the phase-locked loop after the set time SDLY has elapsed from a time point at which the second reset signal RST2 transitions from an enabled state to a disabled state, that is, a time point at which the phase-locked loop starts an operation. In this case, because the operation of the phase-locked loop is at a start stage, the output clock signal PLL_CLK that is output at an initial stage might not synchronized with the second clock signal CLK2 input from the external device (i.e., not in a fully locked state). As a result,, the output clock signal PLL_CLK may not be in an actual used state and may not affect the operations of the phase-locked loop or a semiconductor device including the phase-locked loop.

On the other hand, the clock output component 18 may reflect, in an edge of the output clock signal PLL_CLK of the phase-locked loop, an edge of the first clock signal CLK1 that occurs in the set time SDLY from a time point at which the second reset signal RST2 transitions from a disabled state to an enabled state, that is, a time point at which the operation of the phase-locked loop ends (i.e., is turned off or is initialized). Then, the clock output component 18 may maintain the output clock signal PLL_CLK of the phase-locked loop at a specific logic level (e.g., logic low). In this case, because the phase-locked loop has already operated sufficiently and is being terminated (turned off or initialized), the output clock signal PLL_CLK that is output before the turning off of the phase-locked loop may be already synchronized with the second clock signal CLK2 input from the external device (i.e., in a fully locked state), and may therefore be in an actually used state. Accordingly, toggling of the output clock signal PLL_CLK of the phase-locked loop in an unintended manner within the set time SDLY from a time point at which the operation of the phase-locked loop is terminated may cause malfunction of the phase-locked loop and a semiconductor device including the phase-locked loop.

In summary, during a period from a time point at which the first reset signal RST1, which is input from the external device in a state not synchronized with the first clock signal CLK1, is enabled to a time point at which a second reset signal RST2 is enabled, i.e., during the reset preparation period, the phase-locked loop according to an embodiment may maintain the UP signal DUP in a disabled state and a DOWN signal DDN in an enabled state, through the operation of the phase detector 11. Accordingly, the level of the control voltage OPV generated by the voltage generator 13 may be intentionally decreased, and the frequency of the first clock signal CLK1 generated by the oscillator 14 may be simultaneously reduced. In this way, because the frequency of the first clock signal CLK1 can be forcibly reduced during the reset preparation period, it is possible to prevent a glitch from occurring due to abnormal toggling of the first clock signal CLK1 within the set time SDLY after a time point at which the reset preparation period ends, that is, a time point at which the second reset signal RST2 is enabled.

The lock determiner 16 may generate a lock signal LOCK2 indicating whether the phase-locked loop has completed locking, in response to the UP signal DUP and the DOWN signal DDN. In other words, the lock determiner 16 may determine, in response to the UP signal DUP and the DOWN signal DDN, whether to enable the lock signal LOCK2 depending on whether a phase difference between the second clock signal CLK2 and the third clock signal CLK3 is detected to be equal to or less than a preset phase difference. For example, the lock determiner 16 enables the lock signal LOCK2 when the phase difference between the second clock signal CLK2 and the third clock signal CLK3 is detected to be equal to or less than the preset phase difference. Conversely, the lock determiner 16 disables the lock signal LOCK2 when the phase difference between the second clock signal CLK2 and the third clock signal CLK3 is detected to be greater than the preset phase difference.

In response to the first reset signal RST1 and the second reset signal RST2, the lock determiner 16 may fix, during the reset preparation period, a value of the lock signal LOCK2 that is determined before the reset preparation period. The lock determiner 16 may maintain the value of the lock signal LOCK2, which is determined before the first reset signal RST1 is enabled, from a time point at which the first reset signal RST1 is enabled to a time point at which the second reset signal RST2 is enabled. For example, in the case where the lock signal LOCK2 is determined to be in an enabled state before the reset preparation period, the lock determiner 16 continuously maintains the lock signal LOCK2 in the enabled state during the reset preparation period. Conversely, in the case where the lock signal LOCK2 is determined to be in a disabled state before the reset preparation period, the lock determiner 16 continuously maintains the lock signal LOCK2 in the disabled state during the reset preparation period.

The lock detector 161 included in the lock determiner 16 may determine, in response to an UP signal DUP and a DOWN signal DDN, whether to enable a first lock signal LOCK1 depending on whether a phase difference between the second clock signal CLK2 and the third clock signal CLK3 is detected to be equal to or less than the preset phase difference. The lock determiner 16 may predetermine the preset phase difference based on the number of toggles of the second clock signal CLK2. For example, the lock determiner 16 determines whether the phase difference between the second clock signal CLK2 and the third clock signal CLK3 is equal to or less than the preset phase difference by determining a trend of the UP signal DUP and the DOWN signal DDN, during a period in which the second clock signal CLK2 toggles a preset number of times. It should be noted that various circuit configurations that determine the trend of the UP signal DUP and the DOWN signal DDN in the lock detector 161 are already known, and a detailed description thereof is omitted.

For example, the lock detector 161 enables the first lock signal LOCK1 when a phase difference between the second clock signal CLK2 and the third clock signal CLK3 is detected to be equal to or less than the preset phase difference. Conversely, the lock detector 161 disables the first lock signal LOCK1 when the phase difference between the second clock signal CLK2 and the third clock signal CLK3 is detected to be greater than the preset phase difference.

The stabilizer 162 included in the lock determiner 16 may maintain, in response to the first reset signal RST1 and the second reset signal RST2, a second lock signal LOCK2 in either an enabled state or a disabled state during the reset preparation period, depending on the state of the first lock signal LOCK1 that is determined by the lock detector 161 before the reset preparation period. In this case, the second lock signal LOCK2 output from the stabilizer 162 may refer to the lock signal LOCK2 output from the lock determiner 16.

In other words, when the first lock signal LOCK1 determined by the lock detector 161 before the reset preparation period is in an enabled state, the stabilizer 162 may maintain the second lock signal LOCK2 in an enabled state during the reset preparation period. When the first lock signal LOCK1 determined by the lock detector 161 before the reset preparation period is in a disabled state, the stabilizer 162 may maintain the second lock signal LOCK2 in a disabled state during the reset preparation period.

In summary, the phase-locked loop according to an embodiment may maintain the value of the lock signal LOCK2, which indicates whether the phase-locked loop has completed locking, in either an enabled state or a disabled state during the reset preparation period, through an operation of the stabilizer 162 included in the lock determiner 16. Furthermore, the phase-locked loop may maintain the value of the lock signal LOCK2 regardless of an operation of reducing the frequency of the first clock signal CLK1 through the phase detector 11 during the reset preparation period, thereby preventing the phase-locked loop from malfunctioning due to a change in the fully locked state.

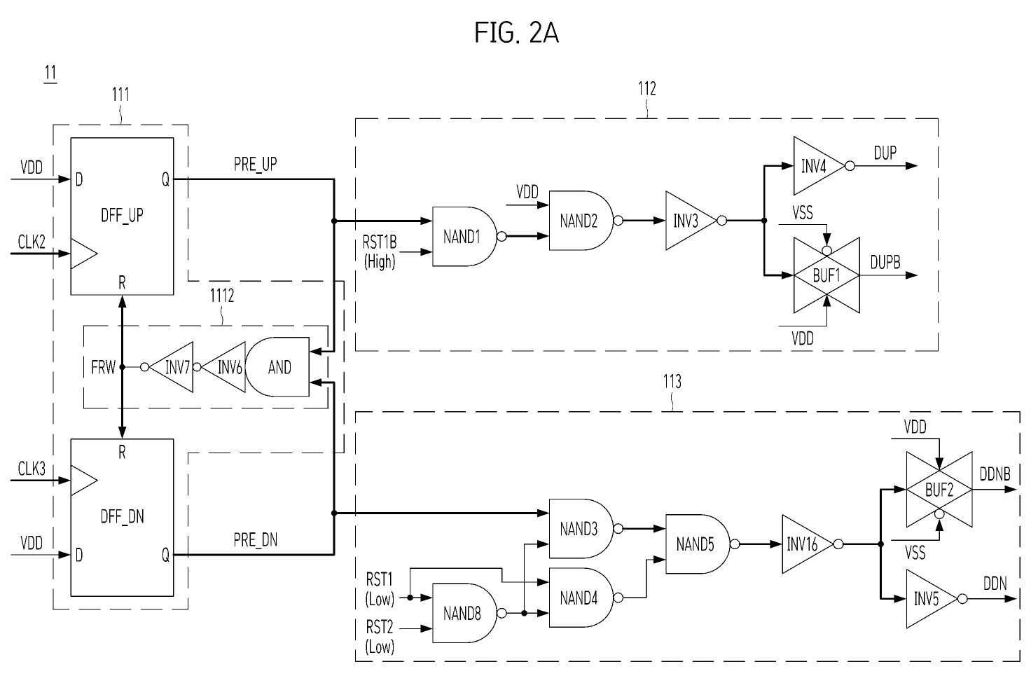

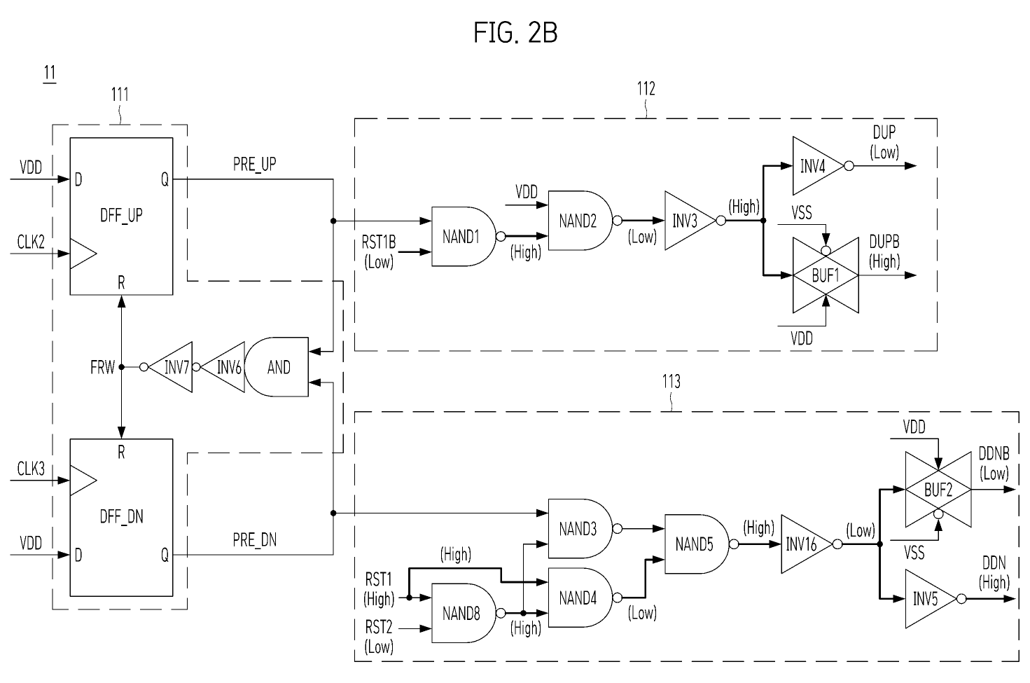

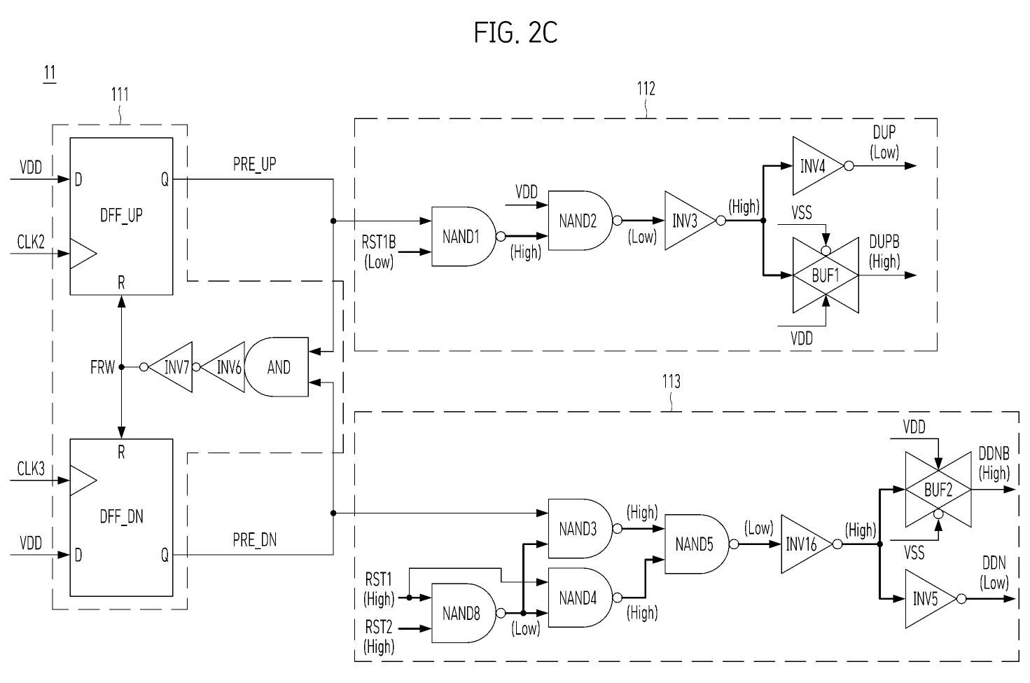

FIGS. 2A-2C are diagrams illustrating a detailed operation of a phase detector among components of the phase-locked loop illustrated in FIG. 1 according to embodiments of the disclosure.

Referring to FIGS. 2A-2C, a phase detector 11 may include a pre-signal generator 111, an UP signal generator 112, and a DOWN signal generator 113.

The pre-signal generator 111 may determine whether to enable a pre-UP signal PRE_UP in response to the second clock signal CLK2. The pre-signal generator 111 may determine whether to enable a pre-DOWN signal PRE_DN in response to the third clock signal CLK3. The pre-signal generator 111 may be initialized in response to both the pre-UP signal PRE_UP and the pre-DOWN signal PRE_DN being enabled.

In an embodiment, the second clock signal CLK2 has a phase leading that of the third clock signal CLK3, and the pre-signal generator 111 enables the pre-UP signal PRE_UP before the pre-DOWN signal PRE_DN. In response to enabling the pre-DOWN signal PRE_DN, the pre-signal generator 111 disables both the pre-UP signal PRE_UP and the pre-DOWN signal PRE_DN. Here, a period from a time point at which the pre-UP signal PRE_UP is enabled to a time point at which the pre-DOWN signal PRE_DN is enabled may represent the amount of time by which the phase of the second clock signal CLK2 leads the phase of the third clock signal CLK3.

In an embodiment, the third clock signal CLK3 has a phase leading that of the second clock signal CLK2, and the pre-signal generator 111 enables the pre-DOWN signal PRE_DN before the pre-UP signal PRE_UP. The pre-signal generator 111 disables both the pre-UP signal PRE_UP and the pre-DOWN signal PRE_DN in response to enabling the pre-UP signal PRE_UP. Here, a period from a time point at which the pre-DOWN signal PRE_DN is enabled to a time point at which the pre-UP signal PRE_UP is enabled may represent the amount of time by which the phase of the third clock signal CLK3 leads the phase of the second clock signal CLK2.

The UP signal generator 112 may output the pre-UP signal PRE_UP as the UP signal DUP when the first reset signal RST1 is in a disabled state at a logic low level, that is, when an inverted signal RST1B of the first reset signal RST1 is in an enabled state at a logic high level. When the first reset signal RST1 is in an enabled state at a logic high level, that is, when the inverted signal RST1B of the first reset signal RST1 is in a disabled state at a logic low level, the UP signal generator 112 may maintain the UP signal DUP in a disabled state at a logic low level.

The DOWN signal generator 113 may output the pre-DOWN signal PRE_DN as the DOWN signal DDN when each of the first reset signal RST1 and the second reset signal RST2 is in a disabled state at a logic low level, that is, when each of the inverted signal RST1B of the first reset signal RST1 and the inverted signal RST2B of the second reset signal RST2 is in an enabled state at a logic high level. The DOWN signal generator 113 may maintain the DOWN signal DDN in an enabled state at a logic high level during the reset preparation period in which the first reset signal RST1 is in an enabled state at a logic high level and the second reset signal RST2 is in a disabled state at a logic low level, that is, the inverted signal RST1B of the first reset signal RST1 is in a disabled state at a logic low level and the inverted signal RST2B of the second reset signal RST2 is in an enabled state at a logic high level. When each of the first reset signal RST1 and the second reset signal RST2 is in an enabled state at a logic high level, that is, when each of the inverted signal RST1B of the first reset signal RST1 and the inverted signal RST2B of the second reset signal RST2 is in a disabled state at a logic low level, the DOWN signal generator 113 may maintain the DOWN signal DDN in a disabled state at a logic low level.

More specifically, the pre-signal generator 111 may include an UP flip-flop DFF_UP, a DOWN flip-flop DFF_DN, and an initialization circuit 1112.

For example, the UP flip-flop DFF_UP outputs a power supply voltage VDD, which is applied to a signal input terminal D, as the pre-UP signal PRE_UP through a signal output terminal Q in response to the second clock signal CLK2 applied to a clock input terminal. In other words, the UP flip-flop DFF_UP may enable the pre-UP signal PRE_UP at a logic high level corresponding to the power supply voltage VDD at an edge (rising or falling edge) of the second clock signal CLK2. Furthermore, the UP flip-flop DFF_UP may disable the pre-UP signal PRE_UP at a logic low level corresponding to a ground voltage, in response to an initialization signal FRW applied to a reset input terminal R.

For example, the DOWN flip-flop DFF_DN outputs a power supply voltage VDD, which is applied to a signal input terminal D, as the pre-DOWN signal PRE_DN through a signal output terminal Q in response to the third clock signal CLK3 applied to a clock input terminal. In other words, the DOWN flip-flop DFF_DN may enable the pre-DOWN signal PRE_DN at a logic high level corresponding to the power supply voltage VDD at an edge (rising or falling edge) of the third clock signal CLK3. In addition, the DOWN flip-flop DFF_DN may disable the pre-DOWN signal PRE_DN at a logic low level corresponding to the ground voltage, in response to the initialization signal FRW applied to a reset input terminal R.

The initialization circuit 1112 may include an AND gate configured to receive the pre-UP signal PRE_UP and the pre-DOWN signal PRE_DN and perform a logical AND operation thereon, and two inverters INV6 and INV7 configured to output a signal resulting from the AND gate as the initialization signal FRW.

The UP signal generator 112 may include: a NAND gate NAND1 configured to receive the inverted signal RST1B of the first reset signal RST1 and the pre-UP signal PRE_UP and perform a logical NAND operation thereon; a NAND gate NAND2 configured to receive an output signal of the NAND gate NAND1 and the power supply voltage VDD and perform a logical NAND operation thereon; an inverter INV3 configured to invert an output signal of the NAND gate NAND2; an inverter INV4 configured to invert an output signal of the inverter INV3 and output the inverted output signal as the UP signal DUP; and a buffer BUF1 configured to buffer an output signal of the inverter INV3 and output the buffered output signal as an inverted signal DUPB of the UP signal DUP.

The DOWN signal generator 113 may include a NAND gate NAND8 configured to receive the first reset signal RST1 and the second reset signal RST2 and perform a logical NAND operation thereon; a NAND gate NAND3 configured to receive an output signal of the NAND gate NAND8 and the pre-DOWN signal PRE_DN and perform a logical NAND operation thereon; a NAND gate NAND4 configured to receive the output signal of the NAND gate NAND8 and the first reset signal RST1 and perform a logical NAND operation thereon; a NAND gate NAND5 configured to receive an output signal of the NAND gate NAND3 and an output signal of the NAND gate NAND4 and perform a logical NAND operation thereon; an inverter INV16 configured to invert an output signal of the NAND gate NAND5; an inverter INV5 configured to invert an output signal of the inverter INV16 and output the inverted output signal as the DOWN signal DDN; and a buffer BUF2 configured to buffer the output signal of the inverter INV16 and output the buffered output signal as an inverted signal DDNB of the DOWN signal DDN.

More specifically, referring to FIG. 2A, it is possible to understand the operation of the phase detector 11 during a period in which a locking operation is performed in the phase-locked loop, with both the first reset signal RST1 and the second reset signal RST2 being in a disabled state at a logic low level, that is, with both the inverted signal RST1B of the first reset signal RST1 and the inverted signal RST2B of the second reset signal RST2 being in an enabled state at a logic high level.

First, the pre-signal generator 111 may perform an operation of enabling either the pre-UP signal PRE_UP or the pre-DOWN signal PRE_DN, whichever is earlier depending on a phase difference between the second clock signal CLK2 and the third clock signal CLK3. The pre-signal generator 111 enables either the pre-UP signal PRE_UP or the pre-DOWN signal PRE_DN regardless of whether both the inverted signal RST1B of the first reset signal RST1 and the inverted signal RST2B of the second reset signal RST2 are enabled at a logic high level.

The UP signal generator 112 may output the pre-UP signal PRE_UP as the UP signal DUP without modification, because the inverted signal RST1B of the first reset signal RST1 is in an enabled state at a logic high level. For example, in response to the pre-UP signal PRE_UP being enabled at a logic high level, the UP signal DUP is enabled at a logic high level and the inverted signal DUPB is disabled at a logic low level.

The DOWN signal generator 113 may output the pre-DOWN signal PRE_DN as the DOWN signal DDN without modification, because both the first reset signal RST1 and the second reset signal RST2 are in a disabled state at a logic low level. For example, in response to the pre-DOWN signal PRE_DN being enabled at a logic high level, the DOWN signal DDN is enabled at a logic high level and the inverted signal DDNB is disabled at a logic low level.

Referring to FIG. 2B, it is possible to understand an operation of the phase detector 11 during a reset preparation period in which the second reset signal RST2 is not enabled after the first reset signal RST1 is input in an enabled state. The first reset signal RST1 is enabled at logic high to turn off or initialize the phase-locked loop performing the locking operation, with the second reset signal RST2 being in a disabled state at a logic low level during the reset preparation period. That is, during the reset preparation period, the inverted signal RST1B of the first reset signal RST1 is disabled at a logic low level and the inverted signal RST2B of the second reset signal RST2 is enabled at a logic high level.

First, the pre-signal generator 111 may perform an operation of enabling either the pre-UP signal PRE_UP or the pre-DOWN signal PRE_DN before the other depending on a phase difference between the second clock signal CLK2 and the third clock signal CLK3, regardless of whether the inverted signal RST1B of the first reset signal RST1 is disabled at a logic low level and regardless of whether the inverted signal RST2B of the second reset signal RST2 is enabled at a logic high level.

Because the inverted signal RST1B of the first reset signal RST1 is in a disabled state at a logic low level, the UP signal generator 112 may disable the UP signal DUP at a logic low level and enable the inverted signal DUPB at a logic high level, regardless of whether the pre-signal generator 111 enables or disables the pre-UP signal PRE_UP.

Because the first reset signal RST1 is enabled at a logic high level and the second reset signal RST2 is disabled at a logic low level, the DOWN signal generator 113 may enable the DOWN signal DDN at a logic high level and disable the inverted signal DDNB at a logic low level, regardless of whether the pre-signal generator 111 enables or disables the pre-DOWN signal PRE_DN.

FIG. 2C illustrates an operation of the phase detector 11 during a period in which the phase-locked loop is turned off or initialized, with both the first reset signal RST1 and the second reset signal RST2 being in an enabled state at a logic high level, that is, with both the inverted signal RST1B of the first reset signal RST1 and the inverted signal RST2B of the second reset signal RST2 being in a disabled state at a logic low level.

First, the pre-signal generator 111 may perform an operation of enabling either the pre-UP signal PRE_UP or the pre-DOWN signal PRE_DN before the other depending on a phase difference between the second clock signal CLK2 and the third clock signal CLK3, regardless of whether both the inverted signal RST1B of the first reset signal RST1 and the inverted signal RST2B of the second reset signal RST2 are disabled at a logic low level.

Because the inverted signal RST1B of the first reset signal RST1 is in a disabled state at a logic low level, the UP signal generator 112 may disable the UP signal DUP at a logic low level and enable the inverted signal DUPB at a logic high level, regardless of whether the pre-signal generator 111 enables or disables the pre-UP signal PRE_UP.

Because both the first reset signal RST1 and the second reset signal RST2 are in an enabled state at a logic high level, the DOWN signal generator 113 may disable the DOWN signal DDN at a logic low level and enable the inverted signal DDNB at a logic high level, regardless of whether the pre-DOWN signal PRE_DN is enabled or disabled

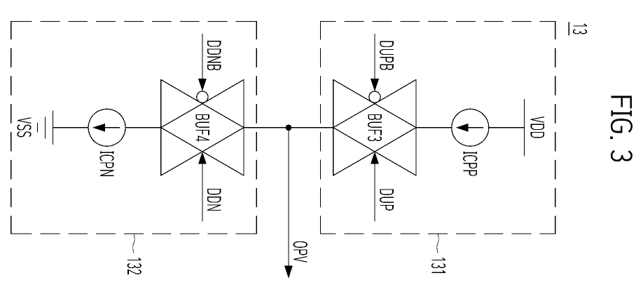

FIG. 3 is a diagram illustrating an example of a circuit of a voltage generator among the components of a phase-locked loop illustrated in FIG. 1 according to an embodiment of the disclosure.

Referring to FIG. 3, a voltage generator 13 may include a level raising component 131, and a level lowering component 132.

For example, when the UP signal DUP generated by the phase detector 11 is in an enabled state at a logic high level and the inverted signal DUPB is in a disabled state at a logic low level, the level raising component 131 raises a level of a control voltage OPV by receiving a current ICPP from a power supply terminal for the power supply voltage VDD.

Conversely, when the UP signal DUP generated by the phase detector 11 is in a disabled state at a logic low level and the inverted signal DUPB is in an enabled state at a logic low level, the level raising component 131 may not raise the level of the control voltage OPV by not receiving the current ICPP from the power supply terminal for the power supply voltage VDD.

When the DOWN signal DDN generated by the phase detector 11 is in an enabled state at a logic high level and the inverted signal DDNB is in a disabled state at a logic low level, the level lowering component 132 lowers the level of the control voltage OPV by sinking the current ICPN to a ground terminal for the ground voltage VSS.

Conversely, when the DOWN signal DDN generated by the phase detector 11 is in a disabled state at a logic low level and the inverted signal DDNB is in an enabled state at a logic low level, the level lowering component 132 does not lower the level of the control voltage OPV by not sinking the current ICPN to the ground terminal for the ground voltage VSS.

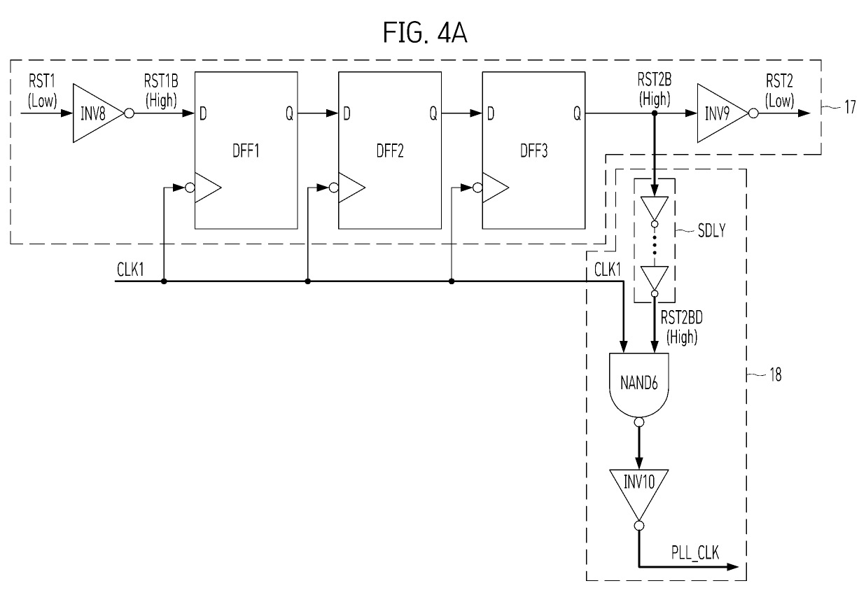

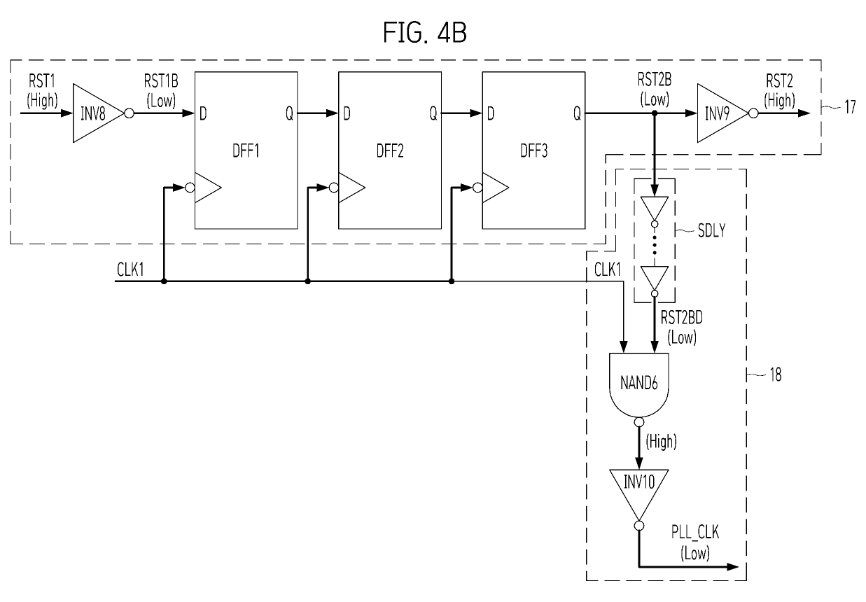

FIGS. 4A and 4B are diagrams illustrating examples of detailed operations of circuits of a reset signal generator and the clock output component among the components of a phase-locked loop illustrated in FIG. 1 according to an embodiment of the disclosure.

Referring to FIGS. 4A and 4B, a reset signal generator 17 may generate a second reset signal RST2 by synchronizing a first reset signal RST1, which is input from an external device, with a first clock signal CLK1.

Specifically, the reset signal generator 17 may include an inverter INV8 configured to invert the first reset signal RST1; a first flip-flop DFF1 configured to output, through a signal output terminal Q, an output signal RST1B of the inverter INV8 applied to a signal input terminal D, in response to the first clock signal CLK1 applied to a clock input terminal; a second flip-flop DFF2 configured to output, through a signal output terminal Q, an output signal of the first flip-flop DFF1 applied to a signal input terminal D, in response to the first clock signal CLK1 applied to a clock input terminal; a third flip-flop DFF3 configured to output, through a signal output terminal Q, an output signal of the second flip-flop DFF2 applied to a signal input terminal D, in response to the first clock signal CLK1 applied to a clock input terminal; and an inverter INV9 configured to invert an output signal RST2B of the third flip-flop DFF3 and output the inverted output signal as a second reset signal RST2.

For reference, although the three flip-flops DFF1, DFF2, and DFF3 are illustrated as being included in the reset signal generator 17 in the drawings, this is merely one embodiment, and actually, any other number of flip-flops may be included in other embodiments.

The clock output component 18 may include an inverter chain configured to delay the inverted signal RST2B of the second reset signal RST2, which is output from the reset signal generator 17, by a set time SDLY and output a delayed signal RST2BD; a NAND gate NAND6 configured to receive the first clock signal CLK1 and the delayed signal RST2BD input from the inverter chain and perform a logical NAND operation thereon; and an inverter INV10 configured to invert an output signal of the NAND gate NAND6 and output the inverted output signal as the output clock signal PLL_CLK of the phase-locked loop.

More specifically, referring to FIG. 4A, an operation of the reset signal generator 17 and the clock output component 18 in response to the first reset signal RST1 being disabled at a logic low level can be understood.

First, the reset signal generator 17 may disable the second reset signal RST2 at a logic low level and enable the inverted signal RST2B at a logic high level, in response to the first reset signal RST1 being disabled at a logic low level. In this case, after three toggles of the first clock signal CLK1 from a time point at which the first reset signal RST1 is disabled at a logic low level, the second reset signal RST2 may be disabled at a logic low level and the inverted signal RST2B may be enabled at a logic high level.

In addition, because the inverted signal RST2B of the second reset signal RST2 is enabled at a logic high level, the delayed signal RST2BD obtained by delaying the inverted signal RST2B of the second reset signal RST2 by the set time SDLY may also be enabled at a logic high level.

When the delayed signal RST2BD, which is obtained by delaying the inverted signal RST2B of the second reset signal RST2 by the set time SDLY, is in an enabled state, the first clock signal CLK1 may be output as the output clock signal PLL_CLK of the phase-locked loop.

Referring to FIG. 4B, an operation of the reset signal generator 17 and the clock output component 18 in response to the first reset signal RST1 being enabled at a logic high level can be understood.

First, the reset signal generator 17 may enable the second reset signal RST2 at a logic high level and disable the inverted signal RST2B at a logic low level, in response to the first reset signal RST1 being enabled at a logic high level. In this case, after three toggles of the first clock signal CLK1 from a time point at which the first reset signal RST1 is enabled at a logic high level, the second reset signal RST2 may be enabled at a logic high level and the inverted signal RST2B may be disabled at a logic low level.

In addition, because the inverted signal RST2B of the second reset signal RST2 is disabled at a logic low level, the delayed signal RST2BD obtained by delaying the inverted signal RST2B of the second reset signal RST2 by the set time SDLY may also be disabled at a logic low level.

When the delayed signal RST2BD obtained by delaying the inverted signal RST2B of the second reset signal RST2 by the set time SDLY is in a disabled state, the output clock signal PLL_CLK of the phase-locked loop may be maintained in a disabled state at a logic low level regardless of toggling of the first clock signal CLK1.

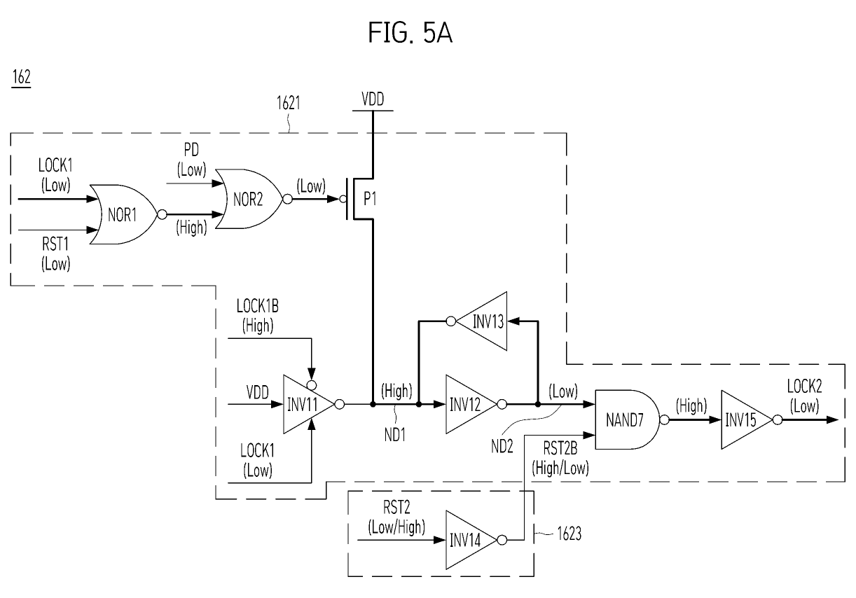

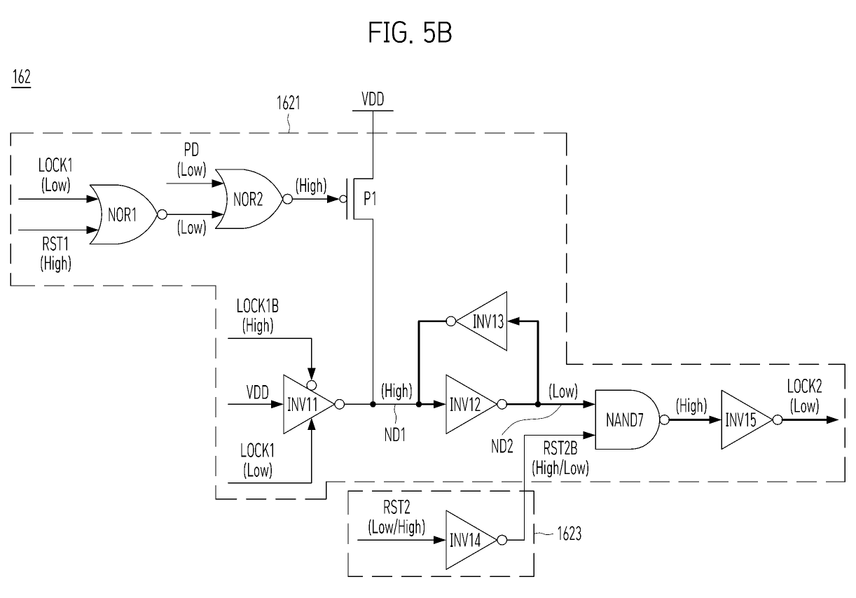

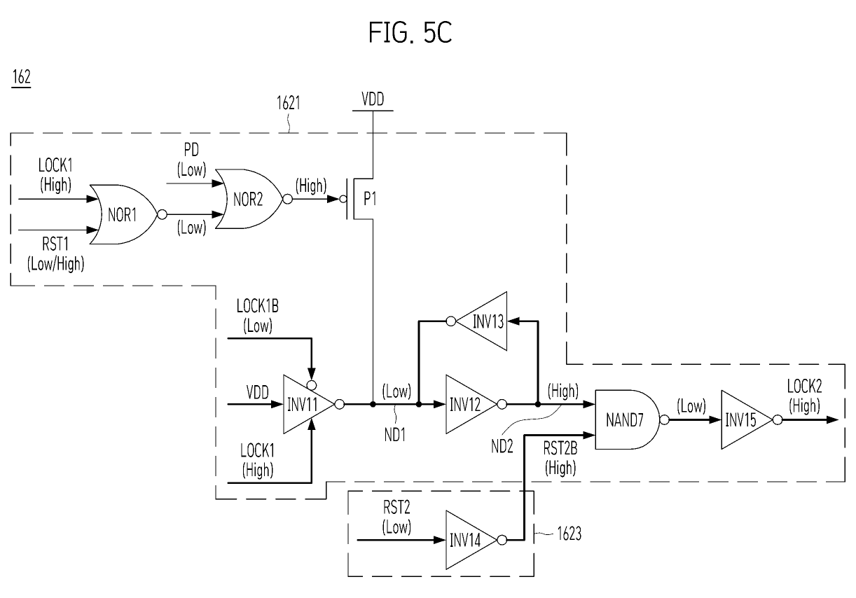

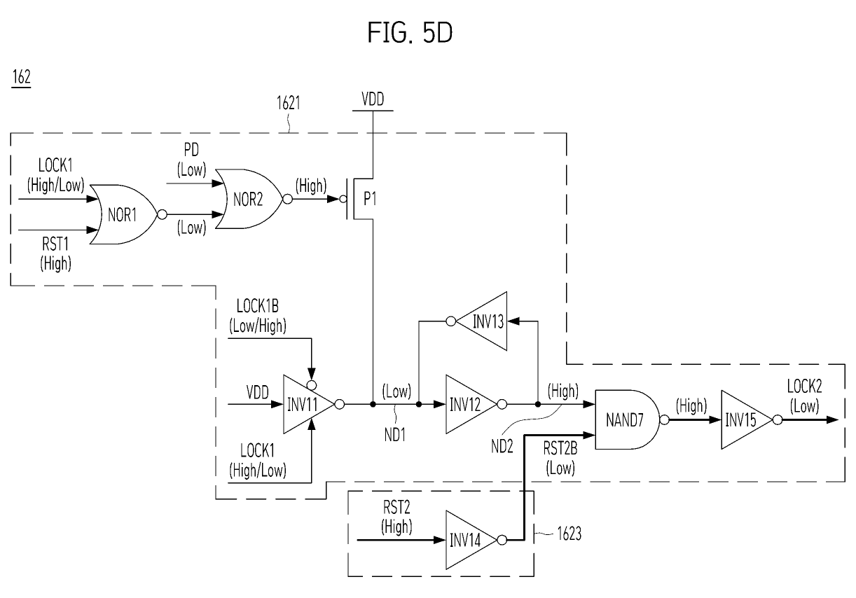

FIGS. 5A-5D are diagrams illustrating examples of detailed operations of a circuit of a stabilizer included in a lock determiner among components of a phase-locked loop illustrated in FIG. 1 according to an embodiment of the disclosure.

Referring to FIGS. 5A-5D, a stabilizer 162 included in a lock determiner 16 may include a second lock signal output circuit 1621 and a disabling control circuit 1623.

First, as described above with reference to FIG. 1, a lock detector 161 included in the lock determiner 16 may determine, in response to an UP signal DUP and a DOWN signal DDN, whether to enable the first lock signal LOCK1 depending on whether a phase difference between the second clock signal CLK2 and the third clock signal CLK3 is detected to be equal to or less than a preset phase difference.

The stabilizer 162 included in the lock determiner 16 may maintain, in response to a first reset signal RST1 and a second reset signal RST2, the second lock signal LOCK2 in an enabled state or a disabled state during a reset preparation period, depending on a state of the first lock signal LOCK1 determined by the lock detector 161 before the reset preparation period.

When the first lock signal LOCK1 determined by the lock detector 161 before the reset preparation period is in an enabled state, the stabilizer 162 may maintain the second lock signal LOCK2 in an enabled state during the reset preparation period. When the first lock signal LOCK1 determined by the lock detector 161 before the reset preparation period is in a disabled state, the stabilizer 162 may maintain the second lock signal LOCK2 in a disabled state during the reset preparation period.

When the first lock signal LOCK1 determined by the lock detector 161 before the reset preparation period is in an enabled state, the second lock signal output circuit 1621 included in the stabilizer 162 may maintain the second lock signal LOCK2 in an enabled state during the reset preparation period. In this case, a state before entering the reset preparation period may refer to a state in which each of the first reset signal RST1 and the second reset signal RST2 is disabled at a logic low level. Furthermore, the reset preparation period may refer to a state in which the first reset signal RST1 is enabled at a logic high level and the second reset signal RST2 is disabled at a logic low level.

When the first lock signal LOCK1 determined by the lock detector 161 before the reset preparation period is in a disabled state, the second lock signal output circuit 1621 may maintain the second lock signal LOCK2 in a disabled state during the reset preparation period.

Specifically, the second lock signal output circuit 1621 may include a NOR gate NOR1 configured to receive a first lock signal LOCK1 and a first reset signal RST1 and perform a logical NOR operation thereon; a NOR gate NOR2 configured to receive an output signal of the NOR gate NOR1 and a power-down signal PD and perform a logical NOR operation thereon; a PMOS transistor P1 configured to selectively connect the power supply terminal for the power supply voltage VDD to a first node ND1 in response to an output signal of the NOR gate NOR2 applied to a gate of the PMOS transistor P1; an inverter INV11 configured to invert the power supply voltage VDD and apply the inverted voltage to the first node ND1 in response to the first lock signal LOCK1 and the inverted signal LOCK1B; a pair of inverters INV12 and INV13 connected in a latch form between the first node ND1 and a second node ND2; a NAND gate NAND7 configured to receive a signal loaded to the second node ND2 and an output signal RST2B of the disabling control circuit 1623 and perform a logical NAND operation thereon; and an inverter INV15 configured to invert an output signal of the NAND gate NAND7 and output the inverted output signal as the second lock signal LOCK2.

The disabling control circuit 1623 may include an inverter INV14 configured to invert the second reset signal RST2 and output the inverted signal as the output signal RST2B.

For reference, in an embodiment, the power-down signal PD is assumed to be a signal fixed at a logic low level as a signal associated with supplying power to the phase-locked loop.

FIG. 5A illustrates the operation of the stabilizer 162 when both the first reset signal RST1 and the second reset signal RST2 are in a disabled state at a logic low level, that is, when the first lock signal LOCK1 is disabled at a logic low level during a period in which the phase-locked loop performs a locking operation, i.e., in the case where locking has not been completed.

In the second lock signal output circuit 1621, because each of the first reset signal RST1 and the first lock signal LOCK1 is in a disabled state at a logic low level, the power supply terminal for the power supply voltage VDD may be connected to the first node ND1 through the PMOS transistor P1, and the second lock signal LOCK2 may remain disabled at a logic low level. For reference, when each of the first reset signal RST1 and the first lock signal LOCK1 is in a disabled state at a logic low level, whether the second reset signal RST2 is enabled or not cannot affect the logic level of the second lock signal LOCK2. Accordingly, as shown in the drawing, the logic level of the second reset signal RST2 is indicated as “Low/High.”

FIG. 5B illustrates an operation of the stabilizer 162 when, from the state shown in FIG. 5A, the first reset signal RST1 transitions from a disabled state at a logic low level to an enabled state at a logic high level, that is, when the first reset signal RST1 is enabled and input to turn off or initialize the phase-locked loop, from a state in which the locking operation of the phase-locked loop has not been completed (FIG. 5A).

In the state shown in FIG. 5A, the power supply voltage VDD is supplied to the first node ND1 through the PMOS transistor P1, so that the second lock signal LOCK2 remains disabled at a logic low level. As illustrated in FIG. 5B, even when the power supply voltage VDD is no longer supplied to the first node ND1 through the PMOS transistor P1 due to the first reset signal RST1 being enabled at a logic high level, the power supply voltage VDD supplied to the first node ND1 may be maintained through the pair of inverters INV12 and INV13 connected in a latch form.

In other words, as illustrated in FIG. 5B, when the first lock signal LOCK1 is in a disabled state at a logic low level, the second lock signal LOCK2 remains disabled at a logic low level even if the first reset signal RST1 transitions from a disabled state at a logic low level to an enabled state at a logic high level. For reference, when the first lock signal LOCK1 is in a disabled state at a logic low level at a time point at which the first reset signal RST1 is enabled at a logic high level, whether the second reset signal RST2 is enabled or not enabled cannot affect the logic level of the second lock signal LOCK2. Accordingly, as shown in the drawing, the logic level of the second reset signal RST2 is indicated as "Low/High."

FIG. 5C illustrates an operation of the stabilizer 162 when, from the state illustrated in FIG. 5A, the first lock signal LOCK1 transitions from a disabled state at a logic low level to an enabled state at a logic high level (i.e., when the locking operation of the phase-locked loop transitions to a fully locked state). Here, the first reset signal RST1 that turns off or initializes the phase-locked loop is in a disabled state at a logic low level, or the reset preparation period in which the first reset signal RST1 is enabled and input at a logic high level while the second reset signal RST2 still remains disabled at a logic low level.

In the state shown in FIG. 5A, the power supply voltage VDD is supplied to the first node ND1 through the PMOS transistor P1, so that the second lock signal LOCK2 remains disabled at a logic low level. Subsequently, when the first lock signal LOCK1 transitions from a disabled state at a logic low level to an enabled state at a logic high level, as shown in FIG. 5C, the power supply voltage VDD is no longer supplied to the first node ND1 through the PMOS transistor P1, and the ground voltage VSS may be supplied to the first node ND1 through an inverter INV11. In the case where the first lock signal LOCK1 is enabled at a logic high level and the ground voltage VSS is supplied to the first node ND1 through an inverter INV11, the second lock signal LOCK2 may be enabled at a logic high level in response to the second reset signal RST2 being disabled at a logic low level.

That is, when the first lock signal LOCK1 is enabled at a logic high level and the ground voltage VSS is thus supplied to the first node ND1 through the inverter INV11, the second lock signal LOCK2 may remain enabled at a logic high level during the period in which the first reset signal RST1, which turns off or initializes the phase-locked loop, is disabled at a logic low level, or during the reset preparation period in which the first reset signal RST1 is enabled at a logic high level while the second reset signal RST2 still remains disabled at a logic low level.

For reference, because the first reset signal RST1 may transition from a disabled state at a logic low level to an enabled state at a logic high level before or after entry into the reset preparation period, the logic level of the first reset signal RST1 is indicated as “Low/High” in the drawing.

5D illustrates an operation of the stabilizer 162 when, after entering the reset preparation period as shown in FIG. 5C, the second reset signal RST2 transitions from a disabled state at a logic low level to an enabled state at a logic high level, thereby terminating the reset preparation period.

In the state shown in FIG. 5C, in response to the first lock signal LOCK1 being enabled at a logic high level before the reset preparation period, the ground voltage VSS is supplied to the first node ND1 through the inverter INV11, and the second lock signal LOCK2 is enabled at a logic high level and maintained in the enabled state at the logic high level during the reset preparation period. Subsequently, as shown in FIG. 5D, when the reset preparation period is terminated in response to the second reset signal RST2 transitioning from a disabled state at a logic low level to an enabled state at a logic high level, the second lock signal LOCK2 may transition from an enabled state at a logic high level to a disabled state at a logic low level.

Referring to FIGS. 5C and 5D together, after entering the reset preparation period, even if the first lock signal LOCK1 transitions from an enabled state at a logic high level back to a disabled state at a logic low level, a second lock signal LOCK2 may remain enabled at a logic high level because the first reset signal RST1 remains enabled. Accordingly, in FIG. 5D, the logic level of the first lock signal LOCK1 is indicated as “High/Low.”

Unlike the case shown in FIG. 5D however, if the first lock signal LOCK1 transitions from an enabled state at a logic high level back to a disabled state at a logic low level before entering the reset preparation period, the stabilizer 162 may operate in the manner described with reference to FIG. 5A so that the second lock signal LOCK2 transitions from an enabled state at a logic high level back to a disabled state at a logic low level.

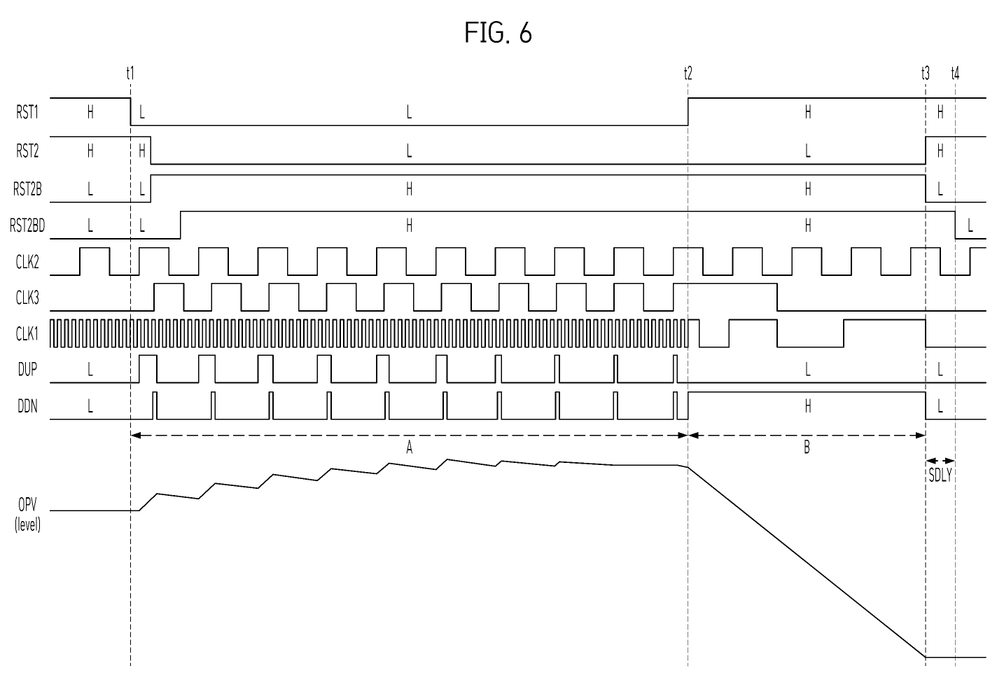

FIG. 6 is a timing diagram during an operation of a phase-locked loop according to an embodiment of the disclosure.

Referring to FIG. 6, at time t1, a locking operation of a phase-locked loop may start when first reset signal RST1 transitions from an enabled state at a logic high level to a disabled state at a logic low level.

During a period “A” from time t1 to time t2, during which the first reset signal RST1 remains disabled at a logic low level until transitioning to an enabled state at a logic high level, the locking operation of the phase-locked loop may be performed. It is assumed in FIG. 6 that, at time t1, the phase of the second clock signal CLK2 leads the phase of the third clock signal CLK3. As a result, the UP signal DUP is repeatedly enabled to a logic high level during the period “A,” and, in response thereto, the level of the control voltage OPV increases in a stepwise manner. It can be understood that in response to the stepwise increase in the level of the control voltage OPV during the period “A,” the phase of the second clock signal CLK2 and the phase of the third clock signal CLK3 gradually approach each other, and immediately before time t2, the second clock signal CLK2 and the third clock signal CLK3 become synchronized.

For reference, the toggling of the DOWN signal DDN during the period “A” is merely a phenomenon that occurs during the initialization of the phase detection operation, that is, during the initialization process of the pre-signal generator 111, as described above with reference to FIGS. 2A-2C. In other words, the toggling of the DOWN signal DDN during the period “A” may not affect the variation in the level of the control voltage OPV in any way.

During a reset preparation period “B” from time t2 to time t3, during which second reset signal RST2 remains disabled at a logic low level until transitioning to an enabled state at a logic high level, the UP signal DUP may be maintained in a disabled state at a logic low level, and the DOWN signal DDN may be maintained in an enabled state at a logic high level. As a result, during the reset preparation period “B,” the level of the control voltage OPV may rapidly decrease. In addition, during the reset preparation period “B,” the frequency of the first clock signal CLK1 and the frequency of the third clock signal CLK3 may also rapidly decrease.

As such, because the frequency of the first clock signal CLK1 and the frequency of the third clock signal CLK3 rapidly decrease during the reset preparation period “B,” the first clock signal CLK1 and the third clock signal CLK3 may stably remain at a logic low level during a period from time t3 to time t4, which is a time point after a set time SDLY from time t3.

In summary, in the phase-locked loop according to an embodiment, during the reset preparation period “B”, which corresponds to a period from a time point at which the first reset signal RST1, input from the external device without being synchronized with the first clock signal CLK1, is enabled, to a time point at which the second reset signal RST2 is enabled, the UP signal DUP is maintained in a disabled state, and the DOWN signal DDN is maintained in an enabled state. The level of the control voltage OPV is thereby intentionally lowered and simultaneously the frequencies of the first clock signal CLK1 and the third clock signal CLK3 reduced. Accordingly, because the frequencies of the first clock signal CLK1 and the third clock signal CLK3 can be forcibly reduced during the reset preparation period “B,” it is possible to prevent a glitch from occurring due to abnormal toggling of the first clock signal CLK1 and the third clock signal CLK3 within the set time SDLY after the end of the reset preparation period, that is, after the time point at which the second reset signal RST2 is enabled.

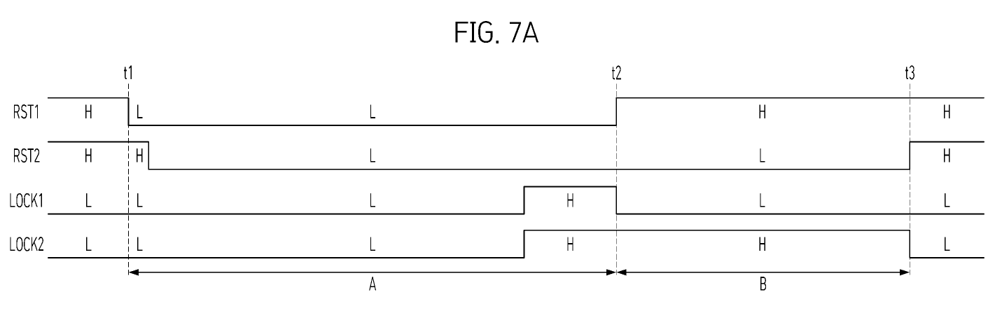

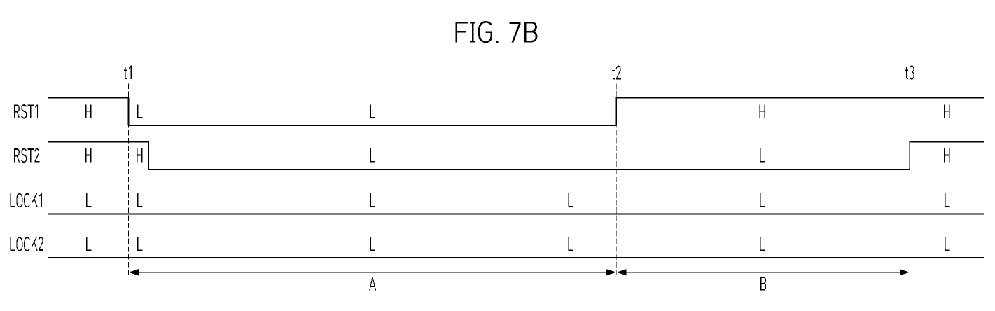

FIGS. 7A and 7B are timing diagrams illustrating an operation of a stabilizer included in a lock determiner among components of a phase-locked loop illustrated in FIG. 1 according to an embodiment of the disclosure.

First, referring to FIGS. 7A and 7B, it can be seen that time t1, time t2, and time t3 described above with reference to FIG. 6 are applied to FIGS. 7A and 7B without modification.

Specifically, referring to FIG. 7A, at time t1, a locking operation of a phase-locked loop may start as first reset signal RST1 transitions from an enabled state at a logic high level to a disabled state at a logic low level.

During a period “A” from time t1 to time t2, during which the first reset signal RST1 remains disabled at a logic low level until transitioning to an enabled state at a logic high level, the locking operation of the phase-locked loop may be performed. As a result of the locking operation, before reaching time t2, each of the first lock signal LOCK1 and the second lock signal LOCK2 may transition from a disabled state at a logic low level to an enabled state at a logic high level. That is, the phase-locked loop may be determined to be in a fully locked state.

As such, after the second lock signal LOCK2 is enabled at a logic high level during the period “A” and the phase-locked loop may be determined to be in a fully locked state, the first lock signal LOCK1 may transition from an enabled state at a logic high level to a disabled state at a logic low level in response to the first reset signal RST1 transitioning from a disabled state at a logic low level to an enabled state at a logic high level at time t2. When the first lock signal LOCK1 transitions from the enabled state to the disabled state, however, the second lock signal LOCK2 may remain enabled at a logic high level. In other words, the second lock signal LOCK2, which is enabled at a logic high level during the period “A” but before time t2, may be maintained in an enabled state at a logic high level during the reset preparation period “B” from time t2 to time t3, during which second reset signal RST2 remains disabled at a logic low level until transitioning to an enabled state at a logic high level.

Subsequently, in response to the second reset signal RST2 transitioning from a disabled state at a logic low level to an enabled state at a logic high level at time t3, that is, in response to the completion of the turn-off or initialization operation of the phase-locked loop upon the end of the reset preparation period, the second lock signal LOCK2 may also transition from an enabled state at a logic high level to a disabled state at a logic low level.

Referring to FIG. 7B, at time t1, a locking operation of a phase-locked loop may start as first reset signal RST1 transitions from an enabled state at a logic high level to a disabled state at a logic low level.

During a section “A” from time t1 to time t2, during which the first reset signal RST1 remains disabled at a logic low level until transitioning to an enabled state at a logic high level, the locking operation of the phase-locked loop may be performed. As a result of the locking operation, until time t2 is reached, each of the first lock signal LOCK1 and the second lock signal LOCK2 may remain disabled at a logic low level. In other words, during section “A”, it may be determined that the phase-locked loop is not in a fully locked state.

As such, if it is determined that the phase-locked loop is not in the fully locked state during the section “A,” and with the second lock signal LOCK2 remaining disabled at a logic low level, the second lock signal LOCK2 may continue to remain disabled at a logic low level even after the first reset signal RST1 transitions from a disabled state at a logic low level to an enabled state at a logic high level at time t2. In other words, the second lock signal LOCK2, which is in a disabled state at a logic low level during the section “A” and before time t2, may be continuously maintained in a disabled state at a logic low level during the reset preparation period “B” from time t2 to time t3, during which the second reset signal RST2 remains disabled at a logic low level until transitioning to an enabled state at a logic high level.

In summary, the phase-locked loop according to an embodiment may fix the value of a lock signal LOCK2, determined during the section “A” and before the reset preparation period, to an enabled state at a logic high level (FIG. 7A) or a disabled state at a logic low level (FIG. 7B) during the reset preparation period. That is, as illustrated in FIG. 6, the value of the lock signal LOCK2 may be fixed during the reset preparation period regardless of a reduction in the frequency of the first clock signal CLK1 during the reset preparation period, thereby preventing the phase-locked loop from malfunctioning due to a change in the fully locked state.

In various embodiments, a phase-locked loop may be controlled such that, when an external reset clock that is not synchronized with an internal clock of the phase-locked loop is enabled and input, an operation of turning off or initializing the phase-locked loop is performed with the internal clock being forcibly reduced in frequency.

Furthermore, in various embodiments, a state of a lock signal of a phase-locked loop may be maintained from a time point at which an external reset clock is enabled and input to a time point at which an operation of turning off or initializing the phase-locked loop is completed.

Accordingly, the phase-locked loop may be stably turned off or initialized.

It will be evident to a person having ordinary knowledge in the art to which the present disclosure pertains that the present disclosure described above is not limited by the aforementioned embodiments and the accompanying drawings and that the present disclosure may be substituted, modified, and changed in various ways without departing from the technical spirit of the present disclosure.

For example, the positions and kinds of the logic gates and transistors described in the above embodiments of the present invention may be different according to the polarity of an inputted signal.

What is claimed is:

1. A phase-locked loop comprising:
a voltage generator configured to generate a control voltage that increases or decreases in voltage level depending on whether each of an UP signal and a DOWN signal is enabled;
an oscillator configured to generate a first clock signal that toggles at a frequency corresponding to a level of the control voltage;
a reset signal generator configured to synchronize a first reset signal input from an external device with the first clock signal, and to generate a second reset signal;
a phase detector configured to detect a phase difference between a second clock signal input from an external device and a third clock signal obtained by feeding back the first clock signal, to determine whether to enable each of the UP signal and the DOWN signal, and to maintain the UP signal in a disabled state and the DOWN signal in an enabled state during a reset preparation period from a time point at which the first reset signal is enabled to a time point at which the second reset signal is enabled; and
a lock determiner configured to generate a lock signal indicating whether locking is completed, in response to the UP signal and the DOWN signal.

2. The phase-locked loop of claim 1, wherein in response to the first reset signal and the second reset signal, the lock determiner fixes, during the reset preparation period, a value of the lock signal that is determined before the reset preparation period.

3. The phase-locked loop of claim 2, wherein the lock determiner comprises:
a lock detector configured to enable, in response to the UP signal and the DOWN signal, a first lock signal when a phase difference between the second clock signal and the third clock signal is detected to be equal to or less than a preset phase difference; and
a stabilizer configured to maintain, in response to the first reset signal and the second reset signal, a second lock signal in either an enabled state or a disabled state during the reset preparation period, depending on a state of the first lock signal that is determined by the lock detector before the reset preparation period.

4. The phase-locked loop of claim 3, wherein the stabilizer comprises:
a second lock signal output circuit configured to maintain the second lock signal in an enabled state during the reset preparation period when the first lock signal determined by the lock detector before the reset preparation period is in an enabled state, and to maintain the second lock signal in an disabled state during the reset preparation period when the first lock signal determined by the lock detector is in a disabled state; and
a disabling control circuit configured to disable the second lock signal in response to the second reset signal being disabled.

5. The phase-locked loop of claim 1, further comprising:
a clock divider configured to output, to the phase detector, the third clock signal generated by dividing the first clock signal at a set ratio; and
a clock output component configured to output the first clock signal as a phase-locked loop output clock signal in response to an inverted signal of the second reset signal.

6. The phase-locked loop of claim 5, wherein the clock output component outputs the first clock signal as the phase-locked loop output clock signal during a period in which a signal obtained by delaying the inverted signal of the second reset signal by a set time is enabled.

7. The phase-locked loop of claim 1, wherein the phase detector comprises:
a pre-signal generator configured to determine whether to enable a pre-UP signal in response to the second clock signal, and to determine whether to enable a pre-DOWN signal in response to the third clock signal, the pre-signal generator being initialized in response to both the pre-UP signal and the pre-DOWN signal being enabled;
an UP signal generator configured to output the pre-UP signal as the UP signal when the first reset signal is in a disabled state, and to maintain the UP signal in a disabled state when the first reset signal is in an enabled state; and
a DOWN signal generator configured to output the pre-DOWN signal as the DOWN signal when both the first reset signal and the second reset signal are in a disabled state, to maintain the DOWN signal in an enabled state during the reset preparation period corresponding to a state in which the first reset signal is in an enabled state and the second reset signal is in a disabled state, and to maintain the DOWN signal in a disabled state when both the first reset signal and the second reset signal are in an enabled state.

8. The phase-locked loop of claim 7, wherein the voltage generator comprises:
a level raising component configured to raise a level of the control voltage when the UP signal is in an enabled state; and
a level lowering component configured to lower the level of the control voltage when the DOWN signal is in an enabled state.

9. The phase-locked loop of claim 8, wherein the oscillator increases a frequency of the first clock signal in response to an increase in the level of the control voltage, and decreases the frequency of the first clock signal in response to a decrease in the level of the control voltage.

10. A method of operating a phase-locked loop, the method comprising:
increasing a level of a control voltage when an UP signal is in an enabled state, and decreasing the level of the control voltage when a DOWN signal is in an enabled state;
generating a first clock signal toggling at a frequency corresponding to the level of the control voltage;
generating a second reset signal by synchronizing a first reset signal input from an external device with the first clock signal;
detecting, when both the first reset signal and the second reset signal are in a disabled state, a phase difference between a second clock signal input from an external device and a third clock signal obtained by feeding back the first clock signal, and determining whether to enable each of the UP signal and the DOWN signal;
maintaining the UP signal in a disabled state and the DOWN signal in an enabled state during a reset preparation period corresponding to a state in which the first reset signal is in a disabled state and the second reset signal is in an enabled state; and
maintaining both the UP signal and the DOWN signal in a disabled state when the both the first reset signal and the second reset signal are in a disabled state.

11. The method of claim 10, further comprising:
generating a lock signal indicating whether locking is completed, in response to the UP signal and the DOWN signal, and
fixing, in response to the first reset signal and the second reset signal, during the reset preparation period, a value of the lock signal that is determined before the reset preparation period.

12. The method of claim 11, further comprising:
enabling, in response to the UP signal and the DOWN signal, a first lock signal when a phase difference between the second clock signal and the third clock signal is detected to be equal to or less than a preset phase difference; and
maintaining, in response to the first reset signal and the second reset signal, a second lock signal in either an enabled state or a disabled state during the reset preparation period, depending on a state of the first lock signal.

13. The method of claim 12, further comprising:
maintaining the second lock signal in an enabled state during the reset preparation period when the first lock signal is in an enabled state;
maintaining the second lock signal in a disabled state during the reset preparation period when the first lock signal is in a disabled state; and
disabling the second lock signal in response to the second reset signal being enabled.

14. The method of claim 10, further comprising:
generating the third clock signal by dividing the first clock signal at a set ratio; and
outputting the first clock signal as a phase-locked loop output clock signal in response to an inverted signal of the second reset signal.

15. The method of claim 14, further comprising:
outputting the first clock signal as the phase-locked loop output clock signal during a period in which a signal obtained by delaying the inverted signal of the second reset signal by a set time is enabled.

16. The method of claim 10, further comprising:
increasing a frequency of the first clock signal in response to an increase in the level of the control voltage, and
decreasing the frequency of the first clock signal in response to a decrease in the level of the control voltage.
